(19) United States
(12) Patent Application Publication
(10) Pub. No.: US 2002/0162742 A1
(43) Pub. Date: Nov. 7, 2002

(54) Cluster tool with vacuum wafer transfer module

(76) Inventors: Jun-Ho Bae, Seoul (KR); Hong-Sik Byun, Seoul (KR)

Correspondence Address: LEWIS F. GOULD, JR., DUANE MORRIS LLP, ONE LIBERTY PLACE, PHILADELPHIA, PA, 19103, US

(21) Appl. No.: 10/136,260

(22) Filed: May 1, 2002

(30) Foreign Application Priority Data
May 2, 2001 (KR) 2001-23668

(51) Int. Cl. C25B 9/00; C25B 13/00; C23C 16/00

(52) U.S. Cl. 204/298.25; 118/715; 438/908

(57) ABSTRACT

A cluster tool for forming semiconductor devices using a wafer process includes: at least a load port where wafers are loaded; a front end system including an ATM robot and an ATM aligner, the front end system positioned under atmospheric pressure in a clean room condition; at least a load lock chamber including at least a vacuum wafer transfer device; at least a process module where the wafer process are conducted on the wafers; and at least a slot valve located between the load lock chamber and the process module; wherein the ATM robot transfers the wafers from the load port to the ATM aligner for a positional aligning and then transfers the positional-aligned wafers to the vacuum wafer transfer device; wherein the ATM aligner aligns the wafers for adequate process in the process module; and wherein the vacuum wafer transfer device includes at least a end effector that supports the wafers transferring by the ATM robot, and then the vacuum transfer device puts the wafers into the process module for the wafer process and takes the processed wafers back from the process module.

This application claims the benefit of Korean Patent Applications No. 2001-23668 filed on May 2, 2001, which is hereby incorporated by reference as if fully set forth herein.

### BACKGROUND OF THE INVENTION

1. Field of the Invention

The present invention relates to an apparatus for manufacturing a semiconductor device, and more particularly to a cluster tool transferring wafers among modules of semiconductor processing.

2. Discussion of the Related Art

The semiconductor devices, such as a memory IC (integrated circuit) and other logic elements, are generally fabricated by repeated depositing and patterning processes. In other words, variable materials are generally formed on a wafer using deposition, etching, cleaning and drying processes. During these processes, the wafer is located inside a process module that provides the optimum atmosphere for each process. Moreover, after each process, the wafer is transferred to the next process module for anther process, and thus a wafer transfer module is required. Such a wafer transfer module is commonly named as a cluster tool that transfers the wafer to the process module and takes the wafer back from the process module for a next continuous process.

The cluster tool usually includes a vacuum transport system that is typically maintained at a reduced pressure, e.g., vacuum conditions such that the cluster tool is commonly termed a vacuum cluster tool. FIG. 1 illustrates a cluster tool architecture diagram, wherein a plurality of process modules are connected, according to a conventional art.

As shown in FIG. 1, the cluster tool includes first and second load ports 10 and 12 where the wafers are firstly loaded, a front end system 20 that transports the wafers that are positioned in the first and second load ports 10 and 12 and then that aligns the wafers, and first and second load lock chambers 30 and 32 where the wafers are introduced into a vacuum transport module 40. The vacuum transport module 40 of the cluster tool interfaces with first and second process modules 50 and 52 such that it transfers the wafers from the first and second load lock chambers 30 and 32 to the first and second process modules 50 and 52 one by one for the processes, such as material deposition and layer etching. The front end system 20 is located under atmospheric pressure in a clean room condition. An ATM (atmosphere) robot 22 is located in the front end system 20 for transferring the wafers loaded in the load ports 10 and 12. Additionally, an ATM (atmosphere) aligner 24 is also located in the front end system 20 for positional aligning the wafers transferred by the ATM robot 22.

The first and second load lock chambers 30 and 32 are located in the center of the system main frame and receive the wafers from the front end system 20. Each of the load lock chambers 30 and 32 includes metal shelves where the wafers are loaded. Although not shown in FIG. 1, valves or doors are located between each of the load lock chambers 30 and 32 and the vacuum transport module 40 and between each of the load lock chambers 30 and 32 and the front end system 20. The valves or doors close the load lock chambers 30 and 32 and vacuum transport module 40, and then, help to maintain the load lock chambers 30 and 32 and vacuum transport module 40 in a vacuous condition. A wafer handling robot 42 located in the vacuum transport module 40 is used to transfer the wafers from the metal shelves of the load lock chambers 30 and 32 to the process modules 50 and 52 one by one, wherein the wafers are sequentially received on wafer receivers 54 and 56 before conducting the processing steps. The wafers may then be transferred, one by one, to another batch process modules, where the wafers undergo additional processing steps.

In the above-mentioned cluster tool, the wafers are transferred from the first and second load ports 10 and 12 to the first and second process modules 50 and 52 through the load lock chambers 30 and 32 and vacuum transport module 40. After finishing the process in each of the process modules 50 and 52, the wafers are sent back to the load ports 10 and 12. The detailed explanation for wafer transport is as follows.

The wafers loaded in the first and second load ports 10 and 12 transfer by the ATM robot 22 of the front end system 20 one by one, and then the wafers are placed in the ATM aligner 24. The ATM aligner 24 aligns the wafers in adequate position for precisely loading the wafers on the wafer receivers 54 and 56 of the process modules 50 and 52. Thereafter, the ATM robot 22 transfers the positional-aligned wafers to the metal shelves of the first and second load lock chambers 30 and 32 one by one, and thus, all wafers are loaded in the metal shelves of the first and second load lock chambers 30 and 32 by repeated transferring of ATM robot 22. The first and second load lock chambers 30 and 32 are then closed by the doors or valves, such that the first and second load lock chambers 30 and 32 and the vacuum transport module 40 can maintain a vacuum environment therein. Thereafter, the wafers loaded in the shelves of the load lock chambers are introduced one by one into the first and second process modules 50 and 52 by the wafer handling robot 42, wherein the process modules 50 and 52 conduct the respective process on the wafers loaded on the wafer receivers 54 and 56.

After finishing the process in the process modules 50 and 52, the wafers are taken back to the metal shelves of the first and second load lock chambers 30 and 32 by the wafer handling robot 42 in an inverse order. When the first and second load lock chambers 30 and 32 are vented up to atmosphere, the valves or doors are opened and then the ATM robot 22 of the front end system 20 transfers the wafers from the first and second load lock chambers 30 and 32 to the first and second load ports 10 and 12. By way of repeating the above-mentioned process, the semiconductor device is accomplished.

However, the above-mentioned cluster tool is substantially large in size because the cluster tool includes the vacuum transport module 40 through which the wafers transfer from the load lock chambers 30 and 32 to the process modules 50 and 52. Therefore, the above cluster tool requires a large installation area when the cluster tool is used in practice. Additionally, it takes a lot of cost when the aforementioned cluster tool is fabricated. Moreover, since the wafers are transferred by a rather complicated way, there is much larger possibility of miss-operating, thereby decreasing the reliability of cluster tool.

### SUMMARY OF THE INVENTION

Accordingly, the present invention is directed to a cluster tool for transferring wafers among modules of semiconductor processing, which substantially obviates one or more of the problems due to limitations and disadvantages of the related art.

An advantage of the present invention is to provide a cluster tool for transferring wafers, which is small in size and occupies a rather small installation area.

Another advantage of the present invention is to provide a cluster tool for transferring wafers, which prevents the miss-operation and increases the process stability.

Another advantage of the present invention is to provide a cluster tool for transferring wafers, which increases the wafer reliability and decreases the manufacturing costs of wafers.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

In order to achieve the above object, the preferred embodiment of the present invention provides a cluster tool for forming semiconductor devices using a wafer process by way of introducing wafers into and removing wafers from process modules. The cluster tool includes at least a load port where wafers are loaded; a front end system including an ATM robot and an ATM aligner, the front end system positioned under atmospheric pressure in a clean room condition; at least a load lock chamber including at least a vacuum wafer transfer device; at least a process module where the wafer process are conducted on the wafers; and at least a slot valve located between the load lock chamber and the process module; wherein the ATM robot transfers the wafers from the load port to the ATM aligner for a positional aligning and then transfers the positional-aligned wafers to the vacuum wafer transfer device; wherein the ATM aligner aligns the wafers for adequate process in the process module; and wherein the vacuum wafer transfer device includes at least a end effector that supports the wafers transferring by the ATM robot, and then the vacuum transfer device puts the wafers into the process module for the wafer process and takes the processed wafers back from the process module.

The vacuum wafer transfer device includes two robot arms that have two links and the end effector at the end thereof, and the two robot arms alternatively transfer the wafers between the load lock chamber and the process module. Substantially, there are two load lock cambers and two process modules, wherein each load lock chamber has one vacuum wafer transfer device and each load lock chamber corresponds to each process module. Each robot arm includes a shaft that is positioned in a predetermined portion of the load lock chamber and drives the first link that is connected to the first shaft for rotation on the pivotal axis of the first shaft. Each robot arm also includes the first and second links that are pivotally connected to each other by a first connector. The end effector is pivotally connected to the second link by a second connector.

In another aspect, there will be two load lock chambers and four process modules and each load lock chamber corresponds to two process modules. In this case, the vacuum wafer transfer device of the first load lock chamber turns counterclockwise in a 90-degree arc or clockwise in a 90-degree arc.

In another aspect, the cluster tool further includes metal shelves in the load lock chamber, where the wafers are loaded; and at least a cooler that refrigerates the wafer loaded in the metal shelves. The metal shelves nest the wafers until the ATM robot transfers all the wafers from the load port, and also nest the processed wafers until the vacuum wafer transfer device takes all the process wafers back from the process module. The cooler in the load lock chamber cools down the processed wafers when the processed wafers are loaded in the metal shelves in considerable numbers.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 illustrates a cluster tool architecture diagram, wherein a plurality of process modules are connected, according to a conventional art;

FIG. 2 schematically illustrates a cluster tool architecture diagram, wherein vacuum wafer transfer devices are installed, according to a first embodiment of the present invention;

FIG. 3 is a perspective view illustrating the cluster tool in detail according to the first embodiment of the present invention;

FIG. 4A is a plan view showing a vacuum wafer transfer device when a left robot extends;

FIG. 4B is a plan view showing the state that the vacuum wafer transfer device holding the wafers within the load lock chamber;

FIG. 4C is a sectional elevation view of the load lock chamber and illustrates the vacuum wafer transfer device holding the wafers within the load lock chamber according to the present invention;

FIG. 5 is a perspective view of the vacuum wafer transfer device according to the present invention;

FIG. 6 schematically illustrates a cluster tool architecture diagram, wherein vacuum wafer transfer devices are installed, according to a second embodiment of the present invention; and

FIGS. 7A and 7B are perspective views illustrating a cluster tool in detail according to a third embodiment of the present invention.

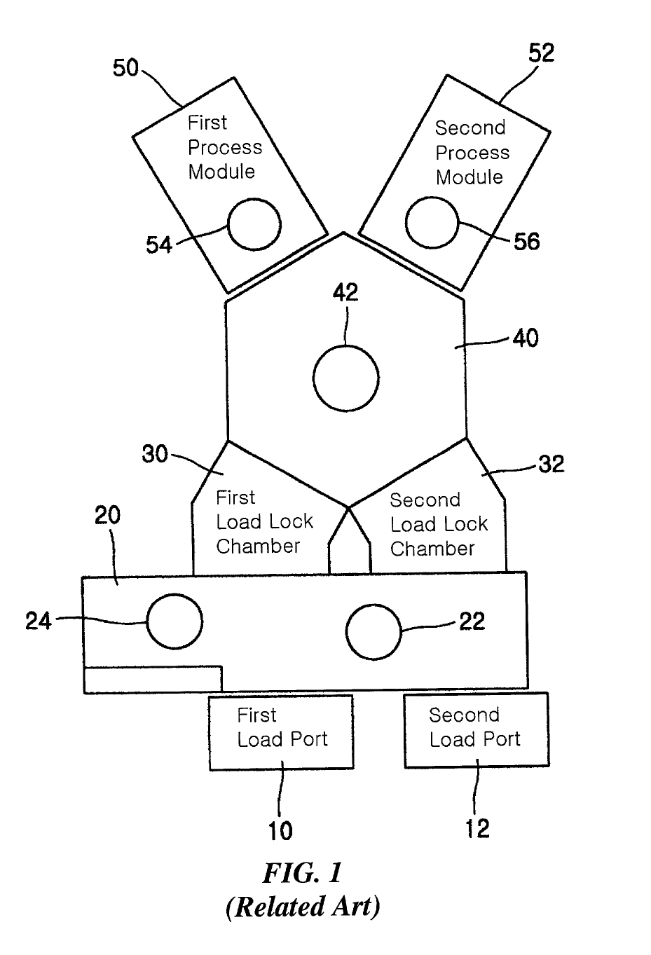

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

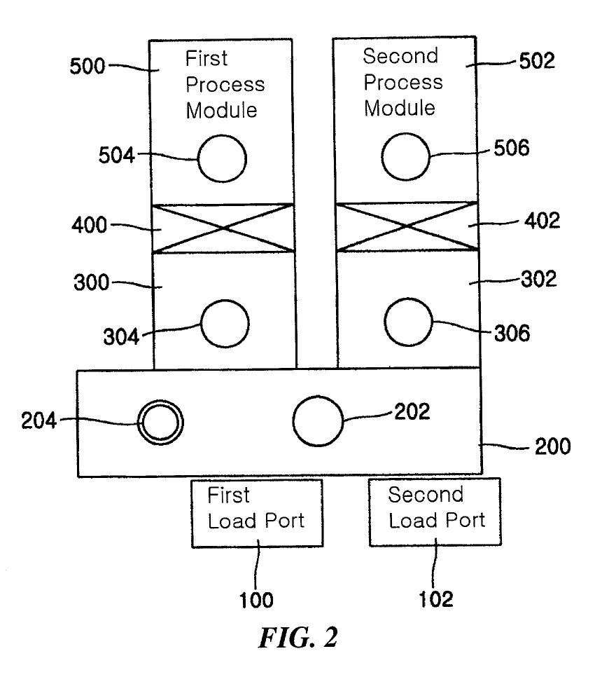

FIG. 2 schematically illustrates a cluster tool architecture diagram, wherein vacuum wafer transfer devices are installed, according to a first embodiment of the present invention. As shown in FIG. 2, the cluster tool includes first and second load ports 100 and 102 where the wafers are firstly loaded, a front end system 200 that transports the wafers from the first and second load ports 100 and 102 and then that aligns the wafers, and first and second load lock chambers 300 and 302 where the wafers are introduced into first and second process modules 500 and 502. The first and second process modules 500 and 502 are interfaced with the first and second load lock chambers 300 and 302, respectively. First and second slot valves 400 and 402 are located between each of the load lock chambers 300 and 302 and each of the process modules 500 and 502, respectively. The first and second slot valves 400 and 402 separate the load lock chambers 300 and 302 from the process modules 500 and 502, such that the load lock chambers can have an environment therein different from the process module.

The front end system 200 is located under atmospheric pressure in a clean room condition. An ATM (atmosphere) robot 202 is located in the front end system 200 for transferring the wafers loaded in the load port 100 and 102. Additionally, an ATM (atmosphere) aligner 204 is also located in the front end system 200 for positional alignment of the wafers transferred by the ATM robot 202.

The first and second load lock chambers 300 and 302 include first and second vacuum wafer transfer devices 304 and 306, respectively. The first and second vacuum wafer transfer devices 304 and 306 are used to transfer the wafers from-the front end system 200 to the first and second process modules 500 and 502 one by one, where the wafers are received by wafer receivers 504 and 506.

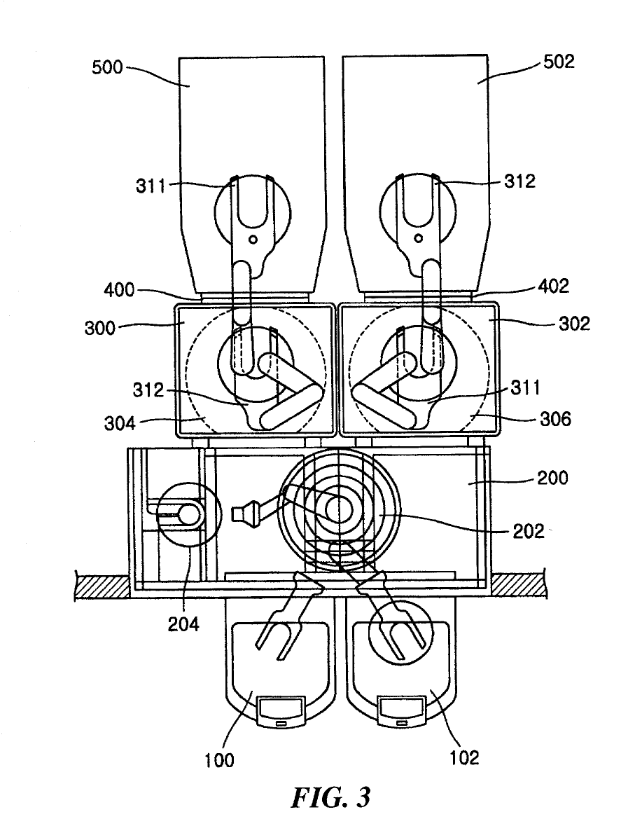

FIG. 3 is a perspective view illustrating the cluster tool in detail according to the first embodiment of the present invention. As shown in FIG. 3, each of the first and second vacuum wafer transfer devices 304 and 306 nested by each of the first and second load lock chambers 300 and 302 includes two robots each having an end effector 311 or 312 for holding a wafer to be transferred to each of the process modules 500 and 502. Each robot has two arms that are connected to each other. Each end effect is connected to the end of one of arms, and thus, the wafers are transferred into the process modules 500 and 502 as the arms of the robot are moved in an extend motion during the wafer transfer.

In FIG. 3, the first vacuum wafer transfer device 304 in the first load lock chamber 300 extends the left robot having the first end effector 311 for transferring the wafer into the first process module 500. The right robot of the first vacuum wafer transfer device 304 is in a state of taking the wafer back from the first process module 500. On the contrary, the second vacuum wafer transfer device 306 in the second load lock chamber 302 extends the right robot having a second end effector 312 for transferring the wafer into the second process module 502, and the right robot of the second vacuum wafer transfer device 306 shrinks to show the state of taking the wafer back from the second process module 502.

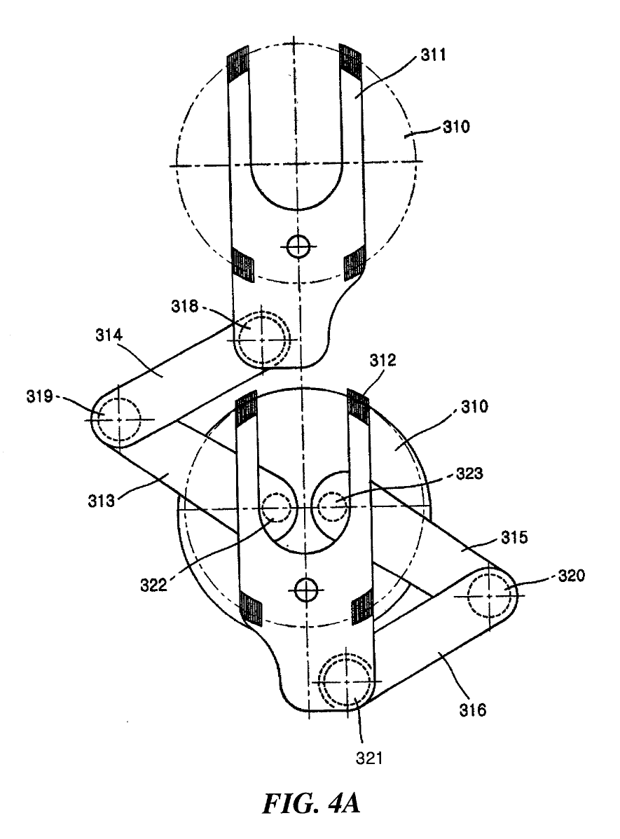

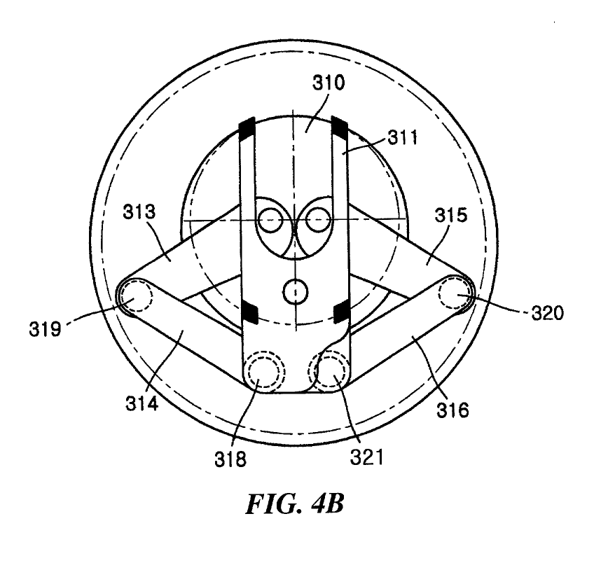

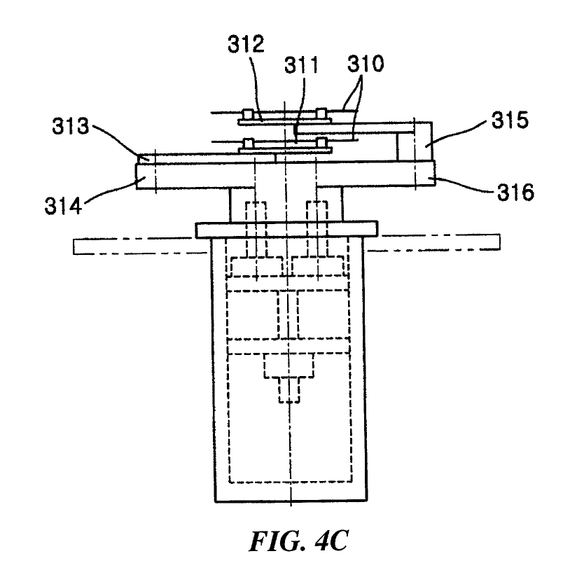

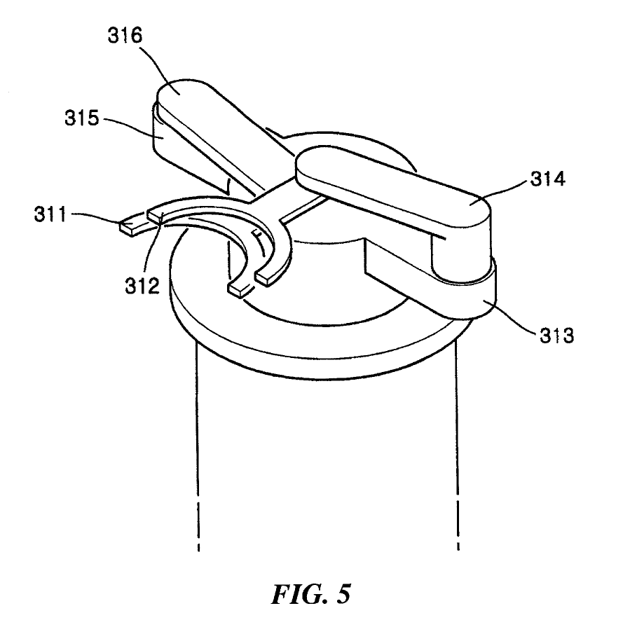

FIG. 4A is a plan view showing a vacuum wafer transfer device when a left robot extends, FIG. 4B is a plan view showing the state that the vacuum wafer transfer device holding the wafers within the load lock chamber, and FIG. 4C is a sectional elevation view of the load lock chamber and illustrates the vacuum wafer transfer device holding the wafers within the load lock chamber according to the present invention. FIG. 5 is a perspective view of the vacuum wafer transfer device according to the present invention. Hereinafter, the first and second vacuum wafer transfer devices 304 and 306 will be explained in detail referring to FIGS. 4A to 4C and 5.

As mentioned before, the first and second vacuum wafer transfer devices 304 and 306 respectively have two robots, i.e., the left robot and the right robot. The left robot includes a first shaft 322, a first link 313, a first connector 319, a second link 314, a second connector 318 and the first end effector 311. The first shaft 322 is positioned in a predetermined portion of the load lock chamber and drives the first link 313 that is connected to the first shaft 322 for rotation on the pivotal axis of the first shaft 322. The first and second connectors 313 and 314 are pivotally connected to each other by the first connector 319, and the first end effector 311 on which the wafer 310 is supported is also pivotally connected to the second link 314. Once the wafer 310 is located on the first end effector 311, the first shaft 322 causes the first and second links 313 and 314 to perform an extend motion or a shrink motion. During the extend motion, the first and second links 313 and 314 position the first end effector 311 for feeding the wafer 310 into the process module as shown in FIG. 3. In this manner, the right robot of each vacuum wafer transfer device includes a second shaft 323 positioned adjacent to the first shaft 322, a third link 315 connected to the second shaft 323, a fourth link 316 connected to the third link 315 by a third connector 320, and the second end effector 312 connected to the fourth link 316 by a fourth connector 312. Once the wafer 310 is located on the second end effector 312, the right robot is operated as the same manner as the left robot, for example, the extend motion or the shrink motion.

Now referring to FIGS. 2 to 5, an operating principle of the cluster tool will be explained in detail according to the present invention. The wafer loaded in the first or second load port 100 or 102 is transferred to the ATM aligner 204 by the ATM robot 202 of the front end system 200. The ATM aligner 204 aligns the wafer in adequate position for precisely loading it on the wafer receivers 504 and 506 of the process modules 500 and 502. Thereafter, the ATM robot 202 transfers the positional-aligned wafer to the first end effector 311 of the first vacuum wafer transfer device 304 in the first load lock chamber 300. In this manner, the other wafer loaded in the first or second load port 100 or 102 is also transferred on the second end effector 312 of the first vacuum wafer transfer device 304 in the first load lock chamber 300 using the ATM robot 202 and ATM aligner 204. Once the two wafers are loaded on the first and second end effector 311 and 312, respectively, the first slot valve 400 of the first load lock chamber 300 is closed, and then the inside of the first load lock chamber 300 is vacuumed.

Thereafter, the first vacuum wafer transfer 304 transfers the wafer located on the first end effect 311 into the first process module 500 by way of extending the first and second links 313 and 314, as described in FIG. 3. Then, the left robot of the first vacuum wafer transfer 304 returns to the first load lock chamber 300 without the wafer, and then stands ready for the wafer process finish in the first process module 500. After finishing the wafer process in the first process module 500, the left robot of the first vacuum wafer transfer device 340 takes the wafer back to the first load lock chamber 300.

After the wafer is taken back to the first load lock chamber 300 using the left robot of the first vacuum wafer transfer device 304, the wafer loaded on the second end effector 312 is put into the first process module 500 for the wafer process. After the wafer process, the right robot of the first vacuum wafer transfer device 304 takes the processed wafer back to the first load lock chamber 300 as the same manner as the left robot did.

When the wafers are back to the first load lock chamber 300, the first slot valve 400 is closed and then the first load lock chamber 300 is vented up to atmosphere. Thereafter, the doors between the load lock chamber 300 and the front end system 200 is opened and then the ATM robot 202 of the front end system 200 picks up the wafers located on the first and second end effectors 311 and 312. The ATM robot 202 transfers the wafers from the first load lock chambers 300 to the first and second load ports 100 and 102.

Accordingly, by way of repeating the above-mentioned process, the semiconductor device is accomplished. At this point, although the operation process of the second load lock chamber 302 is not explained, the wafer process in the second process module 502 and the operation of the second load lock chamber 302 are as the same manner as those of the first load lock chamber 300 and first process module 500.

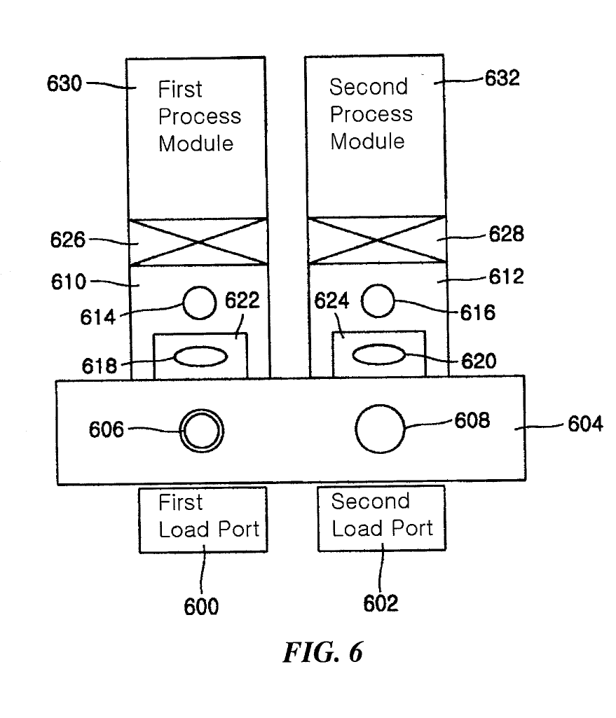

FIG. 6 schematically illustrates a cluster tool architecture diagram, wherein vacuum wafer transfer devices are installed, according to a second embodiment of the present invention. The cluster tool of FIG. 6 has almost same structure and configuration as that of FIG. 2, but there are some differences. Each vacuum wafer transfer device of the second embodiment only includes one robot arm unlike the first embodiment, and the cluster tool of the second embodiment includes at least a cooling system for cooling down the wafers after the wafer process in the process module.

The cluster tool of the second embodiment includes first and second load ports 600 and 602 where the wafers are firstly loaded, and a front end system 604 that is interfaced with the load ports and includes an ATM robot 608 and an ATM aligner 606. The ATM robot 608 transfers the wafers loaded in the first and second load ports 600 and 602, and the ATM aligner 606 serves as positional aligning the wafers. Moreover, the cluster tool of the second embodiment also includes first and second metal shelves 618 and 620 where the wafers transferred from the load ports are loaded, first and second coolers 622 and 624 that refrigerate the wafers loaded in the first and second metal shelves 618 and 620, and first and second load lock chambers 610 and 612 where first and second vacuum wafer transfer devices 614 and 616 are nested, respectively, to transfer the wafers from the first and second metal shelves 618 and 620 into first and second process modules 630 and 632. As mentioned before, each process module conducts the corresponding wafer process. The first and second coolers 622 and 624 refrigerate the wafers when the wafers are loaded in the metal shelves after finishing the wafer process in the corresponding process module. As mentioned before, it is distinguishable from the first embodiment that each of the vacuum wafer transfer device 614 and 616 has just one robot arm with one end effector.

The operation of the second embodiment will be explained as follows. The wafer loaded in the first or second load port 600 or 602 is moved by the ATM robot 608 to the ATM aligner 606, and then the ATM aligner 606 aligns the position of the wafers. The positional-aligned wafers are then loaded in the first and second metal shelves 618 and 620.

By repeating those process, the wafers located in the first and second load ports 600 and 602 are loaded in the first and second metal shelves 618 and 620 one by one. Thereafter, the first and second load lock chambers 610 and 612 close first and second slot valves 626 and 628 and forms a vacuum therein in order to make a clean room condition. The first and second vacuum wafer transfer devices 614 and 616 transfers the wafers loaded in the first and second metal shelves 618 and 620 into the first and second process modules 630 and 632. Each of the process modules conducts the corresponding process on the wafer and then the processed wafers are taken back to the metal shelves 618 and 620 by the first and second vacuum wafer transfer devices 614 and 616. After the wafer process in the process modules, the wafers usually have a temperature of 550 to 780 degrees centigrade, such that they are required to cool down. When the processed wafers are loaded in the first and second metal shelves 618 and 620 in considerable numbers after the wafer process in the process modules 630 and 632, the first and second coolers 622 and 624 work to refrigerate the processed wafers, and at the same time, the first and second load lock chambers 610 and 612 are vent up to atmosphere. Thereafter, the doors between the load lock chambers and the front end system 604 are opened, and then, the ATM robot 608 of the front end system 604 transfers the wafers from the metal shelves 618 and 620 to the first or second load port 600 or 602.

In the second embodiment of the present invention, there are two load ports and two process modules. However, the number of load ports and process modules are not limited. Only one load port or one process module is possible. Moreover, more than three of load ports and process modules can be also employed according to the cluster tool of the present invention.

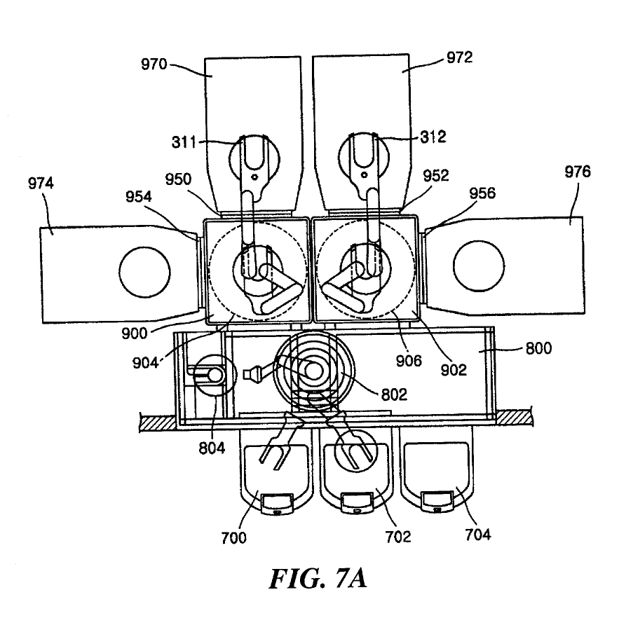

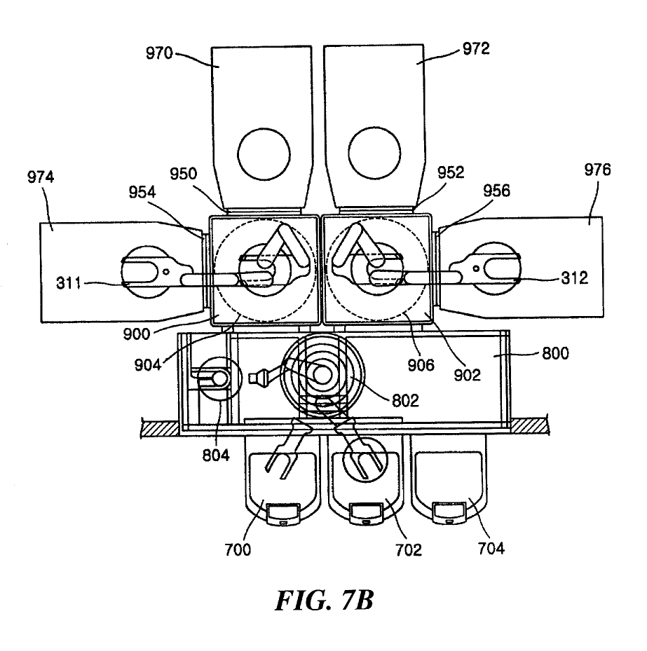

FIGS. 7A and 7B are perspective views illustrating a cluster tool in detail according to a third embodiment of the present invention. In the third embodiment, there are at least three load ports 700, 702 and 704 and fourth process modules 970, 972, 974 and 976. FIG. 7A illustrates a state that a first vacuum wafer transfer device 904 extends the left robot arm having the first end effector 311 to put the wafer into a first process module 970 or to take the processed wafer back from the first process module 970. FIG. 7A also illustrates a state that a second vacuum wafer transfer device 906 extends the right robot arm to put the wafer into a second process module 972 or to tack the processed wafer back from the second process module 972. FIG. 7B shows a state that the left robot arm of the first vacuum wafer transfer device 904 extends for putting the wafer into a third process module 974 or for taking the processed wafer back from the third process module 974, and also shows a state that the right robot arm of the second vacuum wafer transfer device 906 extends for putting the wafer into a fourth process module 976 or for tacking the processed wafer back from the fourth process module 976.

The cluster tool according to the third embodiment of the present invention includes first to third load ports 700, 702 and 704 where the wafer are loaded, and a front end system 800 that has an ATM robot 802 and an ATM aligner 804. The ATM robot 802 transfers the wafers from the load ports 700, 702 and 704 to the ATM aligner 804 that aligns the wafers for the adequate processes in the process modules. The cluster of the third embodiment also includes first and second load lock chambers 900 and 902 in the center of the main frame. The first and second load lock chambers 900 and 902 include the first and second vacuum wafer transfer devices 904 and 906, respectively, which transfer the wafers into the process modules after the ATM robot 802 puts the wafers on first and second end effectors 311 and 312. Additionally, as shown in FIGS. 7A and 7B, the first to fourth process modules 970, 972, 974 and 976 are adjacent to the first and second load lock chambers 900 and 902.

In view of the third embodiment, each of the first and second vacuum wafer transfer devices 904 and 906 has two robot arms each having the end effector. Especially, each vacuum wafer transfer device can rotate clockwise or counterclockwise in a 90-degree arc. First and second slot valves 950 and 952 are located between the first load lock chamber 900 and the first process module 970 and between the second load lock chamber 902 and the second process module 972, respectively. Moreover, third and fourth slot valves 954 and 956 are located between the first load lock chamber 900 and the third process module 974 and between the first load lock chamber 902 and the fourth process module 976, respectively. The first and second vacuum wafer transfer devices 904 and 906 of FIGS. 7A and 7B have the same structure and configuration as that of FIGS. 4A to 4C, but they turn clockwise or counterclockwise in a 90-degree arc by the first and second shafts 322 and 323. Namely, in the third embodiment of the present invention, it is distinguishable that the cluster tool has at least three load ports, four process modules and two vacuum wafer transfer devices.

The wafers loaded in the first to third load ports 700, 702 and 704 are transferred by the ATM robot 802 to the ATM aligner 804. The ATM aligner 804 aligns the wafers for precisely positioning them into the first to fourth process modules 900, 902, 904 and 906. Thereafter, the ATM robot 802 moves the positional-aligned wafers to the first and second vacuum wafer transfer devices 904 and 906 in the first and second load lock chambers 900 and 902. The vacuum wafer transfer devices 904 and 906 transfers the wafers into the corresponding process modules. Since the vacuum wafer transfer devices 904 and 906 make a rotation in a 90-degree arc, the first vacuum wafer transfer device 904 supplies the wafer into the first and third process modules 970 and 974 and the second vacuum wafer transfer device 906 supplies the wafer into the second and fourth process modules 972 and 976. Furthermore, the first to fourth slot valves 950, 952, 954 and 956 are closed to vacuum the load lock chambers and are opened to vent the load lock chambers up to atmosphere, as mentioned before.

After the wafer process in the process modules, the slot valves are opened and then the first and second vacuum wafer transfer devices 904 and 906 take the processed wafers back from the process modules to the first and second load lock chambers 900 and 902. The ATM robot 802 of the front end system 800 picks up the wafers from the vacuum wafer transfer devices and then transfers the processed wafers into the first to third load ports 700, 702 and 704. By repetition of these processes, a number of wafers are processed in the process modules. Additionally in the third embodiment, each of the first and second vacuum wafer transfer devices can have at lease one robot arm, and the first and second load lock chamber can includes the coolers that have the metal shelves.

Accordingly in the present invention, since the load lock chambers include the vacuum wafer transfer devices, the wafers are directly transferred into the process modules for the corresponding processes and then the processed wafers are directly taken back from the process modules. Moreover in the present invention, the manufacturing costs of the cluster tool can decrease and the cluster tool of the present invention occupies rather small installation area. Since the cluster tool of the present invention is simple in operation, the possibility of miss-operation decreases and the cluster tool can be more reliable.

It will be apparent to those skilled in the art that various modifications and variation can be made in the cluster tool having vacuum wafer transfer devices of the present invention without departing from the spirit or scope of the invention. Thus, it is intended that the present invention covers the modifications and variations of this invention provided they come within the scope of the appended claims and their equivalents.

What is claimed is:

1. A cluster tool for forming semiconductor devices using a wafer process, the cluster tool comprising;
at least a load port where wafers are loaded;
a front end system including an ATM robot and an ATM aligner, the front end system positioned under atmospheric pressure in a clean room condition;
at least a load lock chamber including at least a vacuum wafer transfer device;
at least a process module where the wafer process are conducted on the wafers; and
at least a slot valve located between the load lock chamber and the process module;
wherein the ATM robot transfers the wafers from the load port to the ATM aligner for a positional aligning and then transfers the positional-aligned wafers to the vacuum wafer transfer device;
wherein the ATM aligner aligns the wafers for adequate process in the process module; and
wherein the vacuum wafer transfer device includes at least a end effector that supports the wafers transferring by the ATM robot, and then the vacuum transfer device puts the wafers into the process module for the wafer process and takes the processed wafers back from the process module.

2. The cluster tool of claim 1, wherein the vacuum wafer transfer device includes two robot arms each of that have two links and the end effector at the end thereof, and the two robot arms alternatively transfer the wafers between the load lock chamber and the process module.

3. The cluster tool of claim 2, wherein there are two load lock cambers and two process modules, and wherein each load lock chamber has one vacuum wafer transfer device and each load lock chamber corresponds to each process module.

4. The cluster tool of claim 2, wherein each robot arm includes a shaft that is positioned in a predetermined portion of the load lock chamber and drives the first link that is connected to the first shaft for rotation on the pivotal axis of the first shaft.

5. The cluster tool of claim 4, wherein each robot arm includes the first and second links that are pivotally connected to each other by a first connector.

6. The cluster tool of claim 5, wherein the end effector is pivotally connected to the second link by a second connector.

7. The cluster tool of claim 2, wherein there are two load lock chambers and four process modules and each load lock chamber corresponds to two process modules.

8. The cluster tool of claim 7, wherein the vacuum wafer transfer device of the first load lock chamber turns counterclockwise in a 90-degree arc.

9. The cluster tool of claim 8, wherein the vacuum wafer transfer device of the second load lock chamber turns clockwise in a 90-degree arc.

10. The cluster tool of claim 1, further comprising:
metal shelves in the load lock chamber, where the wafers are loaded; and
at least a cooler that refrigerates the wafer loaded in the metal shelves.

11. The cluster tool of claim 10, wherein the metal shelves nest the wafers until the ATM robot transfers all the wafers from the load port.

12. The cluster tool of claim 11, wherein the metal shelves nest the processed wafers until the vacuum wafer transfer device takes all the process wafers back from the process module.

13. The cluster tool of claim 10, wherein the cooler cools down the processed wafers when the processed wafers are loaded in the metal shelves in considerable numbers.

14. The cluster tool of claim 10, wherein there are two load lock chambers and four process modules and each load lock chamber corresponds to two process modules.

15. The cluster tool of claim 14, wherein the vacuum wafer transfer device of the first load lock chamber turns counterclockwise in a 90-degree arc.

16. The cluster tool of claim 15, wherein the vacuum wafer transfer device of the second load lock chamber turns clockwise in a 90-degree arc.
